(19) United States
(12) Patent Application Publication
(10) Pub. No.: US 2004/0245539 A1
(43) Pub. Date: Dec. 9, 2004

(54) Light-emitting diode light string

(76) Inventor: Tien-Yu Chen, Hsing-Chuang City (TW)

Correspondence Address: TROXELL LAW OFFICE PLLC, SUITE 1404, 5205 LEESBURG PIKE, FALLS CHURCH, VA, 22041, US

(21) Appl. No.: 10/455,318

(22) Filed: Jun. 6, 2003

(51) Int. Cl. H01L 33/00

(52) U.S. Cl. 257/99

(57) ABSTRACT

A light-emitting diode light string includes a plurality of lighting modules serially connected to an electric wire. Each lighting module includes a dual-color light emitting diode that serves as a light source of the light string and is removably covered with a facetted shade providing enhanced diffusion and refraction capacity. The light module may be quickly detachably connected to the electric wire through engagement of two corresponding terminals with each other. The dual-color light emitting diode and the facetted shade enable production of changeful and colorful flashes and creation of a unique decorating effect.

### FIELD OF THE INVENTION

The present invention relates to a light-emitting diode (LED) light string, and more particularly to a light-emitting diode light string having lighting modules that can be conveniently detachably connected to an electric wire to produce changeful and colorful flashes and create a unique decorating effect.

### BACKGROUND OF THE INVENTION

Conventional light strings use bulbs as their light source. The bulbs are then covered with light-pervious colored plastic shade in order to produce red, green, yellow or other differently colored light. When the whole light string is lightened, the bulbs flash like stars to create a special decorating effect. Such light strings are widely used in decorating signboards and Christmas trees.

There are many inventions disclosing light strings of different structures For example, Taiwan New Utility Model Patent published under No. 32052 discloses a decorative light string having an overcurrent protection box. The light string includes a plurality of serially or parallelly connected bulbs that are separately set in a plurality of bulb holders. The light string is connected to a plug via conductors for obtaining power from a power source. An overcurrent protection box is provided between the bulb holders and the plug. Conductors connected to two electrodes in the overcurrent protection box are provided with two isolated fuse blocks. The two isolated fuse blocks are separately serially connected to the two conductors of the light string. The conductor used between the overcurrent protection box and the bulb holder, or between any two adjacent bulb holders, is thinner than the conductor used between the overcurrent protection box and the plug.

There are improved light strings using light emitting diodes as the light source thereof. Taiwan Patent published under No. 371402 discloses an LED type Christmas light string that includes an integrally molded LED/base structure for directly mounting in a lamp holder. The LED has two downward extended conducting wires, and the lamp holder has an internal terminal having an L-shaped cross section. When the LED is mounted into the lamp holder, the conducting wires are bent with an end thereof contacting with a horizontal part of the L-shaped terminal and a bent point thereof contacting with a vertical part of the L-shaped terminal. That is, the LED is in contact with the lamp holder at multiple points.

All the conventional LED type Christmas light strings show only mono-colored flashes in a monotonous manner, and include very small lamp bodies that produce only very small light spots. Moreover, pins of the light emitting diodes are hard and tend to bend and break when the light emitting diodes are mounted onto the lamp holders. Since the light emitting diodes are welded to the lamp holders one by one, it is troublesome to repair a failed or damaged lamp. The conventional LED type light string is therefore not suitable for mass production.

It is therefore tried by the inventor to develop an improved LED light string to overcome the drawbacks existed in the prior art.

### SUMMARY OF THE INVENTION

A primary object of the present invention is to provide a light-emitting diode (LED) light string that includes lighting modules for convenient and detachable connection to an electric wire.

Another object of the present invention is to provide a light-emitting diode light string that provides an enhanced light source and produces colorful and changeful flashes.

To achieve the above and other objects, the LED light string of the present invention includes a plurality of lighting modules serially connected to an electric wire. Each lighting module includes a dual-color light emitting diode that serves as a light source of the light string and is covered with a facetted shade providing enhanced diffusion and refraction capacity. The light module may be quickly detachably connected to the electric wire through engagement of two corresponding terminals with each other. The dual-color light emitting diode and the facetted shade enable the production of changeful and colorful flashes and creation of a unique decorating effect.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematical view showing the wiring of LED light string of the present invention;

FIG. 2 is a plan view of a light-emitting diode included in the present invention;

FIG. 3 is an exploded plan view showing a lighting module of the present invention;

FIG. 4 is an assembled plan view of the lighting module of FIG. 3 ready for engaging with a terminal provided on an electric wire; and

FIG. 5 is a circuit diagram of the LED light string of the present invention.

### DETAILED DESCRIPTION OF THE PREFERRED EMBODIMENTS

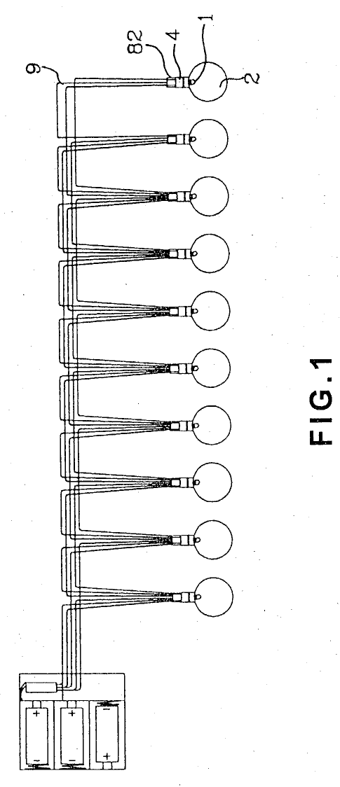

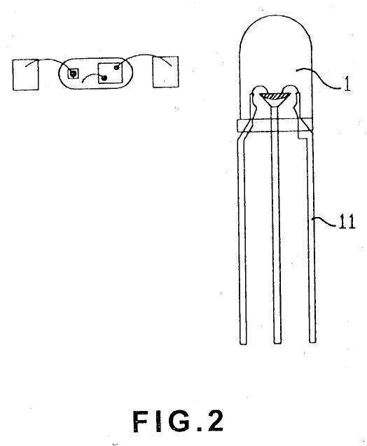

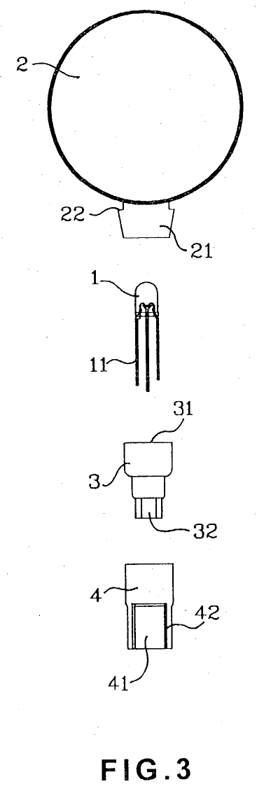

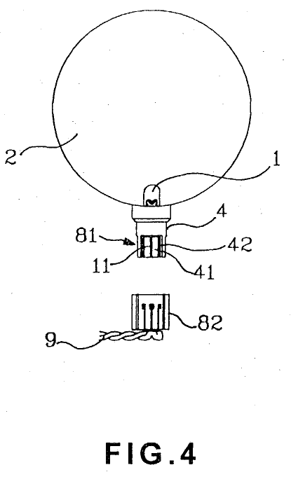

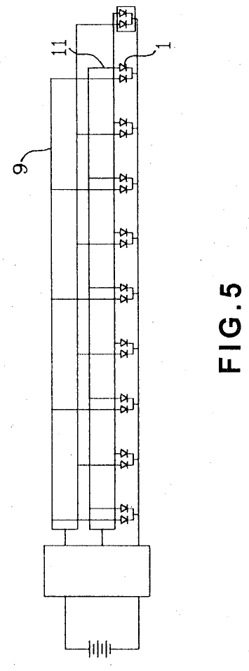

Please refer to FIGS. 1 to 5 in which a light-emitting diode (LED) light string according to the present invention is shown. As shown, the light string of the present invention includes a plurality of serially connected light emitting diodes 1 as a light source thereof. The light emitting diode 1 is a dual-color light emitting diode being removably positioned in a facetted shade 2 that provides enhanced refraction and diffusion capacity. The light emitting diode 1 is connected to an electric wire 9 via engagement of two terminals 81, 82 with each other, and could therefore be conveniently detached from the electric wire 9 for replacement purpose simply by disengaging the two terminals 81, 82 from one another.

The facetted shade 2 has a spherical configuration and is provided at an end with a short connecting head 21, via which a head portion of the light emitting diode 1 is positioned into the facetted shade 2. The short connecting head 21 is provided along an outer peripheral wall with a shoulder portion 22.

The light emitting diode 1 has three pins 11 extended from a rear end of the head portion. The pins 11 are guided into an inner sleeve member 3 via a front opening 31 thereof. The inner sleeve member 3 is provided at a rear end with spaced recesses 32 for each receiving one pin 11 therein. That is, the three pins 11 of the light emitting diode 1 are located in the recesses 32 on the inner sleeve member 3 and spaced from one another.

The inner sleeve member 3 is enclosed in an outer sleeve member 4. The outer sleeve member 4 has a front end that provides an inner space for receiving the inner sleeve member 3 therein and is adapted to engage with the shoulder portion 22 of the short connecting head 21 of the facetted shade 2. A rear end of the outer sleeve member 4 is provided with an opening 41, via which the pins 11 of the light emitting diode 1 are partially exposed to an external environment. Moreover, the opening 41 is provided an outer side with an engaging portion 42.

The light emitting diode 1, the facetted shade 2, the inner sleeve member 3, and the outer sleeve member 4 in an assembled state together forms a lighting module. To assemble the light module, first insert the pins 11 of the light emitting diode 1 into the inner sleeve member 3 via the front opening 31 thereof, and position the head portion of the light emitting diode 1 into the facetted shade 2 via the short connecting head 21. Then, put the outer sleeve member 4 over the inner sleeve member 3 and engage the front end of the outer sleeve member 4 with the shoulder portion 22 on the short connecting head 21. In the lighting module, the pins 11 of the light emitting diode 1 are naturally spaced apart by the recesses 32 at the rear end of the inner sleeve member 3 and partially exposed from the opening 41 on the rear end of the outer sleeve member 4. The exposed pins 11 and the engaging portion 42 formed at the outer side of the opening 41 together constitutes a plugging terminal 81, which may be quickly detachably connected to a socket terminal 82 provided on the electric wire 9. A large number of the lighting modules can therefore be quickly connected to the electric wire 9 to produce the LED light string of the present invention, and easily disconnected therefrom for the purpose of repair or replacement.

Since the light emitting diodes 1 included in the LED light string of the present invention are dual-color light emitting diodes, light flashing in a cyclic manner to show more lively changes may be obtained. For example, when the LED light string of the present invention includes dual-color light emitting diodes showing red and green colors, a red light emitting diode is first made to produce the red color, and a green light emitting diode is then made to produce an orange color obtained through blending of the red and the green color. The red light emitting diode is than disconnected for the green LED to show the green color. When a subsequent red LED is made, the orange color is produced again. In this manner, different colors may be frequently switched to show on the light string. In practical use of the LED light string, dual-color light emitting diodes 1 separately showing two different colors may be freely arranged in the light string to produce more changeful and splendid colors, making the LED light string of the present invention a unique decoration.

The present invention has been described with a preferred embodiment thereof and it is understood that many changes and modifications in the described embodiment can be carried out without departing from the scope and the spirit of the invention as defined by the appended claims.

What is claimed is:

1. A light-emitting diode light string, comprising a plurality of lighting modules serially connected to an electric wire; each of said lighting modules including:
a dual-color light emitting diode serving as a light source of said light string and including a head portion and pins extended from a rear end of said head portion;
a facetted shade having a spherical configuration and being provided at an end with a short connecting head, via which said head portion of said light emitting diode is removably positioned into said facetted shade; and said short connecting head being provided along an outer peripheral wall with a shoulder portion;
an inner sleeve member having a front opening, via which said pins of said light emitting diode are guided into said inner sleeve member, and a rear end provided with spaced recesses for each receiving one of said pins therein to thereby space said pins from one another; and
an outer sleeve member having a front end that provides an internal space for receiving said inner sleeve member therein and is adapted to engage with said shoulder portion of said short connecting head of said facetted shade, and a rear end being provided with an opening via which said pins of said light emitting diode are partially exposed to an external environment; and said opening being provided an outer side with an engaging portion for engaging with a terminal correspondingly provided on said electric wire;
whereby said lighting modules may be quickly detachably connected to said electric wire through engagement of said engaging portions on said outer sleeve members with said terminals on said electric wire to enable quick production and repair of said light string, and said dual-color light emitting diodes enable production of changeful and colorful flashes to create a good decorating effect.
